(19) United States
(12) Patent Application Publication
(10) Pub. No.: US 2007/0159092 A1
(43) Pub. Date: Jul. 12, 2007

(54) Enhanced brightness light emitting device

(75) Inventor: Kai-Shon Tsai, Lujhou City (TW)

Correspondence Address: BACON & THOMAS, PLLC, 625 SLATERS LANE, FOURTH FLOOR, ALEXANDRIA, VA, 22314, US

(73) Assignee: Luminoso Photoelectric Technology Co., Ltd., Lujhou City (TW)

(21) Appl. No.: 11/330,331

(22) Filed: Jan. 12, 2006

(51) Int. Cl. H01L 33/00

(52) U.S. Cl. 313/512; 313/112; 257/98; 257/100; 257/E33.061; 257/E33.059; 428/690

(57) ABSTRACT

There is provided an enhanced brightness light emitting device, comprising a light emitting element, and a transparent encapsulation layer which encloses the light emitting element. The transparent encapsulation layer includes a resin and a fluorescent material represented by the following general formula (I): 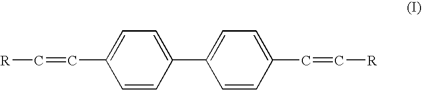 wherein R is selected from one of the group consisting of phenyl substituted with alkoxy, substituted or unsubstituted anthracene group, substituted or unsubstituted pyrene group, and substituted or unsubstituted 9,10-anthraquinone group.

### BACKGROUND OF THE INVENTION

1. Field of the Invention

The present invention generally relates to a light emitting device, and in particular to an enhanced brightness light emitting device in order to solve the problems of color spots and halo phenomena occurred in the conventional light emitting diodes (LED).

2. The Prior Arts

The fluorescent materials can be applied in many fields, and mainly in cleaner (such as soaps and detergents), paper, textile, plastic, oil, painting, and the like. With the development of science and technology, the applied range of fluorescent materials has been increased. For example, the fluorescent materials can be applied in the fluorescent probes, lasers, and especially in the LED. Recently, in the LED technology, most of the researches have been focused on the inorganic system. However, the inorganic compounds can cause the problems of heavy metal pollution, and metal radiation. Furthermore, the light emitted by the conventional LED usually appears color spots (black or yellow spots) and halo phenomena due to its low brightness.

Thus, a need exists for an environmental-friendly light emitting device having high brightness and high luminous efficiency, and not showing color spots (such as black or yellow spots), and halo phenomena.

### SUMMARY OF THE INVENTION

The objective of the present invention is to provide an enhanced brightness light emitting device with high brightness in order to overcome the problems set forth above.

To achieve the foregoing objective, the present invention provides an enhanced brightness light emitting device, comprising a light emitting element, and a transparent encapsulation layer which encloses the light emitting element. The transparent encapsulation layer includes a resin and a fluorescent material represented by the following general formula (I): 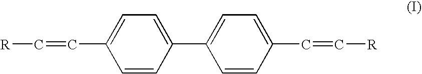
wherein R is selected from one of the group consisting of phenyl substituted with alkoxy, substituted or unsubstituted anthracene group, substituted or unsubstituted pyrene group, and substituted or unsubstituted 9,10-anthraquinone group.

The enhanced brightness light emitting device of the present invention can further comprise a photoluminescent phosphor disposed over the light emitting element, which can emit a second light upon excitation, wherein the first light emitted by the light emitting element can excite the photoluminescent phosphor, which subsequently emits a second light which has longer wavelength than the first light, and the second light and the first light unabsorbed by the photoluminescent phosphor are combined in the encapsulation layer including the resin and the fluorescent material represented by the above general formula (I), and then the fluorescent material is excited and emits a visible light with high brightness and high luminous efficiency outwards from the encapsulation layer.

It is worthy to be noticed that the fluorescent material represented by the above general formula (1) can substantially completely absorb the light having a wavelength between 254 nm and 475 nm, and subsequently re-emit it with very high brightness, and thereby the problems of color spots (such as black or yellow spots) and halo phenomena occurred in the conventional LED can be eliminated. Moreover, the fluorescent materials used in the present invention are environmental-friendly materials, and they will not cause heavy metal pollution, and harmful metal radiation problems. Furthermore, the used amount of the fluorescent material of the present invention for achieving high brightness is low.

On the other hand, the utensils coated with the fluorescent materials of the present invention can have anti-UV function, and moreover a light can easily penetrate through a board coated with the fluorescent materials of the present invention.

The foregoing and other objects, features, aspects and advantages of the present invention will become better understood from a careful reading of a detailed description provided herein below with appropriate reference to the accompanying drawings.

### BRIEF DESCRIPTION OF THE DRAWINGS

FIG. 1 is a cross-sectional view of the enhanced brightness light emitting device according to one embodiment of the present invention;

FIG. 2 is brightness (LM)-time curves illustrating the variation in the brightness of the light emitting device corresponding to its encapsulation layer (in the case of silicone resin) containing, or not containing the fluorescent material (in the case of 4,4′-bis(2-methoxystyryl)biphenyl) measured at the height of 30 cm, and 50 cm every 24 hours, respectively; and

FIG. 3 is brightness increment (%)-time curves illustrating the increased brightness percentage of the light emitting device corresponding to its encapsulation layer (in the case of silicone resin) containing the fluorescent material (in the case of 4,4′-bis(2-methoxystyryl)biphenyl) relative to its encapsulation layer not containing the fluorescent material at the height of 30 cm, and 50 cm every 24 hours, respectively.

### DETAILED DESCRIPTION OF THE PREFERRED EMBODIMENT

The present invention provides an enhanced brightness light emitting device, comprising a light emitting element which can emit a first light, and a transparent encapsulation layer which encloses the light emitting element. The transparent encapsulation layer includes a resin and a fluorescent material represented by the following general formula (I): 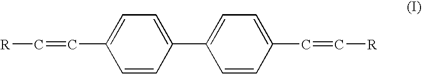
wherein R is selected from one of the group consisting of phenyl substituted with alkoxy, substituted or unsubstituted anthracene group, substituted or unsubstituted pyrene group, and substituted or unsubstituted 9,10-anthraquinone group.

The enhanced brightness light emitting device of the present invention can further comprise a photoluminescent phosphor disposed over the light emitting element which can emit a first light, wherein the first light emitted by the light emitting element can excite the photoluminescent phosphor, which subsequently emits a second light which has longer wavelength than the first light, and the second light and the first light unabsorbed by the photoluminescent phosphor are combined in the encapsulation layer including the resin and the fluorescent material represented by the above general formula (I), and then the fluorescent material is excited and emits a light with enhanced brightness and luminous efficiency outwards from the encapsulation layer.

Specifically, the fluorescent material used in the present invention can be 4,4′-bis(2-methoxystyryl)biphenyl, 4,4′-bis {2-(9-anthracenyl)ethylenyl}biphenyl, 4,4′-bis {2-(1 -pyrenyl)ethylenyl}biphenyl, or 4,4′-bis {2-(1 -anthraquinonyl) ethylenyl}biphenyl. The above-mentioned four fluorescent materials are characterized in that they are symmetric biphenyl type compounds with two ethylenyl groups at 4,4′positions, and the biphenyl type compounds with two ethylenyl groups at 4,4′ positions are bonded to the fluorescent functional groups through two ethylenyl groups. Examples of the fluorescent functional groups are methoxyphenyl group and its homologous; anthracene group and its homologous; pyrene group and its homologous; and 9,10-anthraquinone group and its homologous. The fluorescent materials having the above-mentioned characteristics can substantially completely absorb the light having wavelength between 254 nm and 475 nm, and subsequently re-emits it as a visible light with very high brightness. When 4,4′-bis(2-methoxystyryl)biphenyl is used as the fluorescent material, it can be excited by UV light and subsequently emits a blue light having a wavelength between 450 nm and 490 nm. When 4,4′-bis{2-(9-anthracenyl) ethylenyl}biphenyl is used as the fluorescent material, it can be excited by UV light and subsequently emits a yellowish-green light having a wavelength between 520 nm and 550 nm. When 4,4′-bis{2-(1-pyrenyl)ethylenyl}biphenyl is used as the fluorescent material, it can be excited by UV light and subsequently emits a blue light having a wavelength between 450 nm and 490 nm. When 4,4′-bis{2-(1-anthraquinonyl) ethylenyl}biphenyl is used as the fluorescent material, it can be excited by UV light and subsequently emits a red light having a wavelength between 580 nm and 660 nm. On the other hand, the resin of the transparent encapsulation layer can be silicone resin, or epoxy resin.

The fluorescent material of the present invention is present in an amount of from 0.1 to 10% by weight, preferably from 0.1 to 1% by weight, based on the total weight of transparent encapsulation layer. The resin is present in an amount of from 99.9 to 90% by weight, preferably from 99.9 to 99% by weight, based on the total weight of transparent encapsulation layer.

The photoluminescent phosphor can be a blue phosphor that emits blue light at a wavelength from 450 nm to 490 nm when excited by the electromagnetic radiation of the light emitting element; a yellowish green phosphor that emits yellowish green light at a wavelength from 520 nm to 550 nm when excited by the electromagnetic radiation of the light emitting element; or a red phosphor that emits red light at a wavelength from 580 nm to 660 nm when excited by the electromagnetic radiation of the light emitting element.

In order to achieve the optimum brightness level, in the enhanced brightness light emitting device of the present invention, the blue phosphor is used with 4,4′-bis(2-methoxystyryl)biphenyl, or 4,4′-bis {2-(1 -pyrenyl)ethylenyl} biphenyl to convert the emission of the light emitting element to the blue light; the yellowish green phosphor is used with 4,4′-bis{2-(9-anthracenyl)ethylenyl}biphenyl to convert the emission of the light emitting element to the yellowish green light; and the red phosphor is used with 4,4′-bis{2-(1-anthraquinonyl) ethylenyl}biphenyl to convert the emission of the light emitting element to the red light.

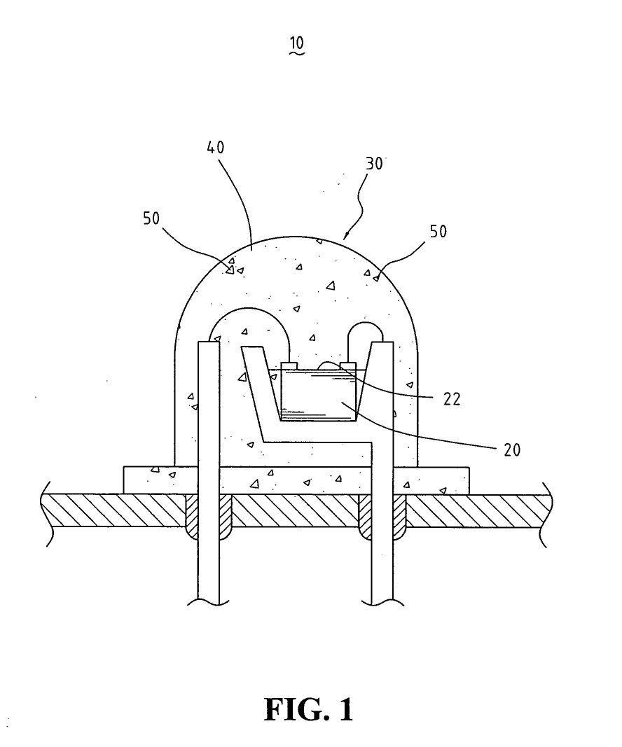

FIG. 1 is a cross-sectional view of the enhanced brightness light emitting device according to one embodiment of the present invention. In FIG. 1, the light emitting element 20 of the enhanced brightness light emitting device 10 is GaN chip which can emit UV light or blue light outwards from the output surface 22. The transparent encapsulation layer 30 is formed by mechanically mixing the silicone resin 40 with the fluorescent material of 4,4′-bis(2-methoxystyryl)biphenyl 50 in an organic solvent, applying the mixture around the light emitting element 20, and drying it. The fluorescent material is present in an amount of from 0.1 to 1% by weight. The resin is present in an amount of from 99.9 to 99% by weight, based on the total weight of transparent encapsulation layer.

Brightness Test

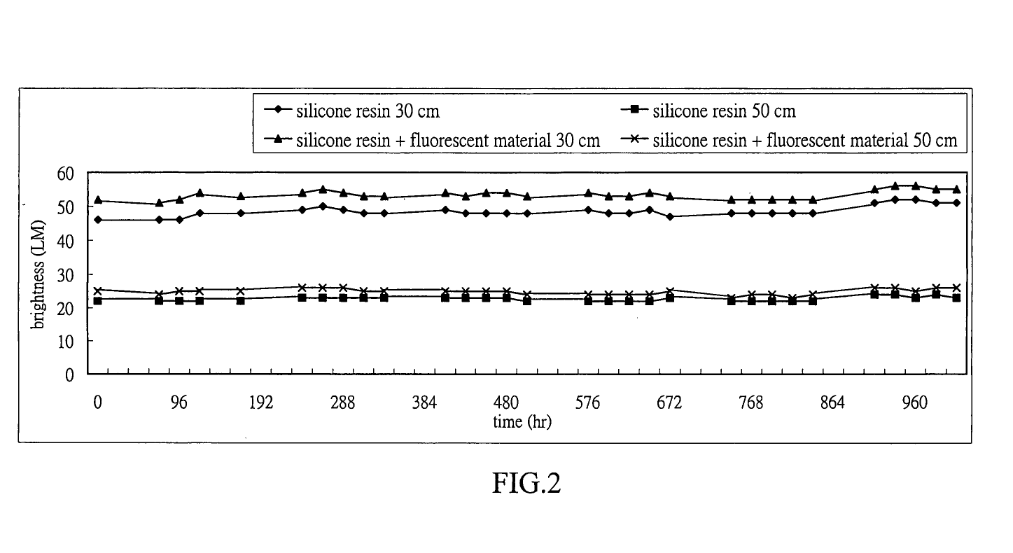

The light emitting element 20 emits a blue light with a wavelength of 465 nm when subjected to a voltage of 3.6 V, and when the blue light with a wavelength of 465 nm passes through the transparent encapsulation layer 30 including the silicone resin 40 and the fluorescent material of 4,4′-bis(2-methoxystyryl)biphenyl 50, the fluorescent material 50 converts the blue light at a wavelength of 465 nm into the blue light at a wavelength of 480 nm. The brightness (LM) of the blue light at a wavelength of 480 nm is measured at the height of 30 cm, and 50 cm every 24 hours, respectively, until the total measured time reaches a setting value of 1008 hours. The above test results are plotted in FIG. 2.

In a similar way, in the case of without the fluorescent material of 4,4′-bis(2-methoxystyryl)biphenyl 50 in the transparent encapsulation layer 30, the light emitting element 20 emits a blue light at a wavelength of 465 nm when subjected to a voltage of 3.6 V, and the blue light is then emitted outwards from the transparent encapsulation layer 30. The brightness (LM) of the blue light is measured at the height of 30 cm, and 50 cm every 24 hours, respectively, until the total measured time reaches a setting value of 1008 hours. The above test results are also plotted in FIG. 2.

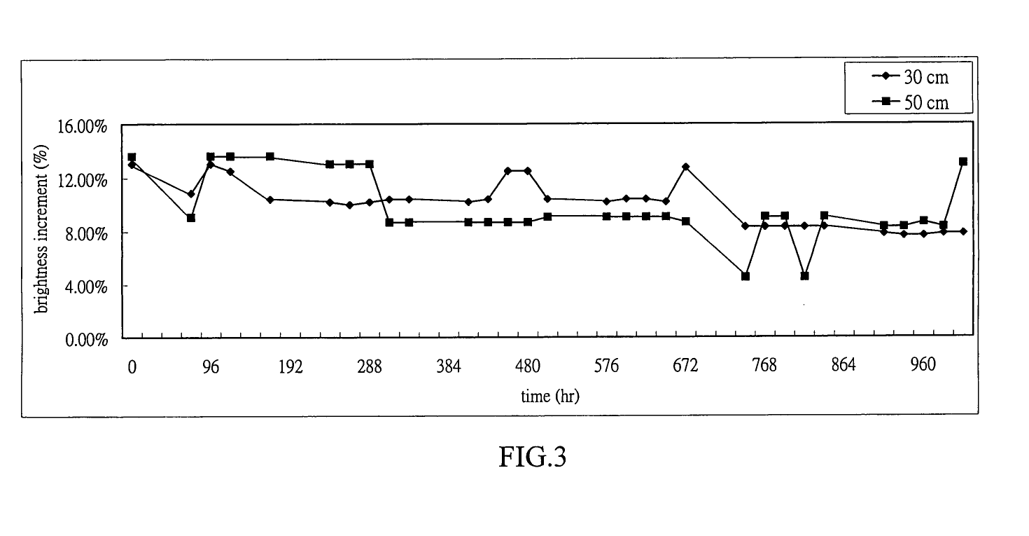

The brightness increment percentage obtained from the data shown in FIG. 2 is plotted in FIG. 3. The brightness increment percentage is calculated by dividing the brightness of the emitted blue light after passing through the transparent encapsulation layer 30 including both silicone resin 40 and the fluorescent material of 4,4′-bis(2-methoxystyryl)biphenyl 50 by the brightness of the emitted blue light after passing through the transparent encapsulation layer 30 only including silicone resin 40 at the height of 30 cm, and 50 cm, respectively (the total measured time is 1008 hours). The average brightness increment percentage at the height of 30 cm is 10.06%, and the average brightness increment percentage at the height of 50 cm is 9.74%. Therefore, if the transparent encapsulation layer of the the light emitting device contains the fluorescent material of 4,4′-bis(2-methoxystyryl)biphenyl 50, the brightness of the emitted light will be greatly enhanced, and thereby the problems of color spots (such as black or yellow spots) and halo phenomena occurred in the conventional LED can be eliminated.

Light-Emitting Efficiency Test

The light emitting element 20 is allowed to emit a first light having a wavelength of 365 nm, 375 nm, 395 nm, and 420 nm, respectively, as powered by the power supply, and then a second light with longer wavelength than the first light is emitted outwards from the the transparent encapsulation layer 30 including silicone resin 40 and the fluorescent material of 4,4′-bis(2-methoxystyryl)biphenyl 50 as shown in FIG. 1. The residual light intensity, consumption intensity, and the intensity of the excited light are measured and calculated. The consumption intensity is obtained by subtracting the residual light intensity from the exciting light intensity. The light-emitting efficiency is obtained by dividing the intensity of the excited light by the consumption intensity. These results are shown in Table 1.

TABLE 1
Light-Emitting Efficiency

| | | Transparent encapsulation | | | |
|---|---|---|---|---|---|
| | | layer including silicone resin | | | |
| | | and 4,4′-bis(2-methoxystyryl)biphenyl | | | |
| | | | | | Light- |
| Exciting light | | | | | emitting |
| Wave- | | Residual | Consumption | Intensity of | effi- |
| length | Intensity | intensity | intensity | excited light | ciency |
| (nm) | (cd) | (cd) | (cd) | (cd) | (%) |
| 365 | 9.622024 | 0.4514948 | 9.1705292 | 3.78128 | 41.23% |
| 375 | 16.11016 | 0.7569989 | 15.3531611 | 4.759387 | 31.00% |
| 395 | 28.78808 | 1.419859 | 27.368221 | 6.282627 | 22.96% |
| 420 | 57.89266 | 2.580826 | 55.311834 | 7.07375 | 12.79% |

As seen from Table 1, when the exciting light having a wavelength of 365 mn is used, the light-emitting efficiency is the best.

Table 2 shows the wavelengths and the CIE chromaticity coordinates of the excited lights in this test.

TABLE 2

Excited light

| Exciting light | | CIE chromaticity |
|---|---|---|
| Wavelength (nm) | Wavelength (nm) | coordinates |
| 365 | 480 | x = 0.1477, y = 0.2193 |
| 375 | 480 | x = 0.1468, y = 0.2189 |
| 395 | 480 | x = 0.1449, y = 0.2175 |
| 420 | 480 | x = 0.1439, y = 0.2177 |

As seen from Table 2, the excited lights all fall in the range of the blue light spectrum.

The fluorescent materials of the present invention used in the transparent encapsulation layer of the light-emitting device have the advantages of: (1) these fluorescent materials are environmental-friendly materials, and will not cause heavy metal pollution, and harmful metal radiation problems; (2) the used amount of these fluorescent materials is low; (3) the operation is easy; and (4) the brightness of the light emitted by the light emitting element can be greatly enhanced through these fluorescent materials so that the problems of color spots (such as black or yellow spots) and halo phenomena occurred in the conventional LED can be eliminated.

It will be apparent to those skilled in the art that various modifications and variations can be made in the present invention without departing from the spirit or scope of the present invention. Thus, it is intended that the present invention cover the modifications and the variations of this invention provided they come within the scope of the appended claims and their equivalents.

What is claimed is:

1. An enhanced brightness light emitting device, comprising:
a light emitting element; and
a transparent encapsulation layer enclosing the light emitting element, the transparent encapsulation layer including a resin and a fluorescent material represented by the following general formula (I): 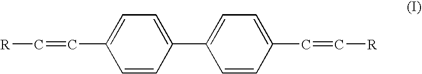
wherein R is selected from one of the group consisting of phenyl substituted with alkoxy, substituted or unsubstituted anthracene group, substituted or unsubstituted pyrene group, and substituted or unsubstituted 9,10-anthraquinone group.

2. The enhanced brightness light emitting device as claimed in claim 1, wherein the light emitting element is a GaN chip.

3. The enhanced brightness light emitting device as claimed in claim 1, wherein the resin is silicone resin, or epoxy resin.

4. The enhanced brightness light emitting device as claimed in claim 1, wherein the resin is present in an amount of from 90 to 99.9% by weight of total weight of the encapsulation layer.

5. The enhanced brightness light emitting device as claimed in claim 1, wherein the fluorescent material is present in an amount of from 10 to 0.1% by weight of total weight of the encapsulation layer.

6. The enhanced brightness light emitting device as claimed in claim 1, wherein the fluorescent material is 4,4′-bis(2-methoxystyryl)biphenyl.

7. The enhanced brightness light emitting device as claimed in claim 1, wherein the fluorescent material is 4,4′-bis{2-(9-anthracenyl)ethylenyl}biphenyl.

8. The enhanced brightness light emitting device as claimed in claim 1, wherein the fluorescent material is 4,4′-bis{2-(1-pyrenyl)ethylenyl}biphenyl.

9. The enhanced brightness light emitting device as claimed in claim 1, wherein the fluorescent material is 4,4′-bis{2-(1-anthraquinonyl) ethylenyl}biphenyl.

10. An enhanced brightness light emitting device, comprising:
a light emitting element being capable of emitting a first light;
a photoluminescent phosphor disposed over the light emitting element, the photoluminescent phosphor emitting a second light at a wavelength longer than the first light when excited by the first light; and
a transparent encapsulation layer enclosing the light emitting element and the photoluminescent phosphor, the transparent encapsulation layer including a resin and a fluorescent material represented by the following general formula (I): 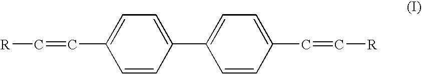
wherein R is selected from one of the group consisting of phenyl substituted with alkoxy, substituted or unsubstituted anthracene group, substituted or unsubstituted pyrene group, and substituted or unsubstituted 9,1 0-anthraquinone group, and
wherein the second light, and the first light unabsorbed by the photoluminescent phosphor are combined in the encapsulation layer including the resin and the fluorescent material, and then the fluorescent material is excited and emits a visible light outwards from the encapsulation layer.

11. The enhanced brightness light emitting device as claimed in claim 10, wherein the light emitting element is a GaN chip.

12. The enhanced brightness light emitting device as claimed in claim 10, wherein the first light has a wavelength between 254 mn and 475 nm.

13. The enhanced brightness light emitting device as claimed in claim 10, wherein the resin is silicone resin, or epoxy resin.

14. The enhanced brightness light emitting device as claimed in claim 10, wherein the photoluminescent phosphor is a blue phosphor that emits a blue light at a wavelength from 450 nm to 490 nm when excited by the first light emitted from the light emitting element.

15. The enhanced brightness light emitting device as claimed in claim 10, wherein the photoluminescent phosphor is a yellowish-green phosphor that emits a yellowish-green light at a wavelength from 520 mn and 550 nm when excited by the first light emitted from the light emitting element.

16. The enhanced brightness light emitting device as claimed in claim 10, wherein the photoluminescent phosphor is a red phosphor that emits a red light at a wavelength from 580 nm and 660 nm when excited by the first light emitted from the light emitting element.

17. The enhanced brightness light emitting device as claimed in claim 10, wherein the resin is present in an amount of from 90 to 99.9% by weight of total weight of the encapsulation layer.

18. The enhanced brightness light emitting device as claimed in claim 10, wherein the fluorescent material is present in an amount of from 10 to 0.1% by weight of total weight of the encapsulation layer.

19. The enhanced brightness light emitting device as claimed in claim 10, wherein the fluorescent material is 4,4′-bis(2-methoxystyryl)biphenyl.

20. The enhanced brightness light emitting device as claimed in claim 10, wherein the fluorescent material is 4,4′-bis{2-(9-anthracenyl)ethylenyl}biphenyl.

21. The enhanced brightness light emitting device as claimed in claim 10, wherein the fluorescent material is 4,4′-bis{2-(1-pyrenyl)ethylenyl}biphenyl.

22. The enhanced brightness light emitting device as claimed in claim 10, wherein the fluorescent material is 4,4′-bis{2-(l-anthraquinonyl) ethylenyl}biphenyl.

23. The enhanced brightness light emitting device as claimed in claim 10, wherein the fluorescent material is 4,4′-bis(2-methoxystyryl)biphenyl, and the photoluminescent phosphor is a blue phosphor that emits a blue light at a wavelength from 450 nm to 490 nm when excited by the first light emitted from the light emitting element.

24. The enhanced brightness light emitting device as claimed in claim 10, wherein the fluorescent material is 4,4′-bis{2-(1-pyrenyl)ethylenyl}biphenyl, and the photoluminescent phosphor is a blue phosphor that emits a blue light at a wavelength from 450 nm to 490 nm when excited by the first light emitted from the light emitting element.

25. The enhanced brightness light emitting device as claimed in claim 10, wherein the fluorescent material is 4,4′-bis{2-(9-anthracenyl)ethylenyl}biphenyl, and the photoluminescent phosphor is a yellowish-green light phosphor that emits a yellowish-green light at a wavelength from 520 nm to 550 nm when excited by the first light emitted from the light emitting element.

26. The enhanced brightness light emitting device as claimed in claim 10, wherein the fluorescent material is 4,4′-bis{2-(1-anthraquinonyl)ethylenyl}biphenyl, and the photoluminescent phosphor is a red phosphor that emits a red light at a wavelength from 580 nm to 660 nm when excited by the first light emitted from the light emitting element.
